(19) United States
(12) Patent Application Publication
(10) Pub. No.: US 2023/0060476 A1
(43) Pub. Date: Mar. 2, 2023

(54) DISPLAY TRANSMISSION OPTIMIZATION

(71) Applicant: ams International AG, JONA (CH)

(72) Inventor: Matthew SAMPSELL, Melissa, TX (US)

(73) Assignee: ams International AG, JONA (CH)

(21) Appl. No.: 17/793,134

(22) PCT Filed: Jan. 7, 2021
(86) PCT No.: PCT/EP2021/050182

§ 371 Date: Jul. 15, 2022

Related U.S. Application Data
(60) Provisional application No. 62/962,491, filed on Jan. 17, 2020.

(51) Int. Cl. H01L 27/32; G01S 7/481

(52) U.S. Cl. CPC H01L 27/3258; H01L 27/3234; H01L 27/3269; G01S 7/4813

(57) ABSTRACT

A system comprises a display and one or more sensors, the one or more sensors being located beneath the display. The display comprises an array of light emitting diodes and associated transistors supported by a substrate. The display further comprises two or more layers of insulator material. The thicknesses of the layers are optimized to allow transmission of infrared radiation and/or visible radiation through the layers and onto the one or more sensors.

### TECHNICAL FIELD OF THE DISCLOSURE

The disclosure relates to display transmission optimization, particularly but not exclusively, to optimization of the transmission of mobile phone displays.

### BACKGROUND OF THE DISCLOSURE

The present disclosure relates to optimization of the transmission of a display, which may for example form part of a mobile phone.

A mobile phone conventionally comprises a housing which holds a display. The display may for example be an LED array (e.g. an OLED array) which may be used to display content such as photographs, websites, emails, etc. to a user. One or more sensors or sensing systems may be provided beneath the display. In one example, a proximity sensing system may be provided beneath the display. Radiation is emitted from a radiation source of the proximity sensing system which is located beneath the display. Some of this radiation is reflected from objects in the vicinity of the mobile phone and is incident upon a detector which is also located beneath the display. A measured time of flight of the radiation indicates the distance between the mobile phone and the object. In another example, an ambient light sensor is located beneath the display. The ambient light sensor measures the intensity of light incident on the display. The measured intensity of the ambient light is sometimes used to adjust the intensity of light emitted by the display in order to optimize the viewing experience, optimize battery life, inform photography, etc.

A problem associated with conventional mobile phones is that the amount of radiation incident upon the one or more sensors beneath the display is relatively low. This may cause poor performance of the one or more sensors.

It is therefore an aim of the present disclosure to address one or more of the problems above.

### SUMMARY

In general, this disclosure proposes to overcome the above problems by optimizing the transmission of infrared radiation and/or visible radiation by material layers of a display, for example through selection of thicknesses of the layers of material. This arrangement is advantageous because it improves the transmission of the display without requiring significant changes to be made to the manner in which the display is manufactured, or to the materials which are used to manufacture the display.

According to one aspect of the present disclosure, there is provided a system comprising a display and one or more sensors, the one or more sensors being located beneath the display, wherein the display comprises an array of light emitting diodes and associated transistors supported by a substrate, wherein the display further comprises two or more layers of insulator material, and wherein thicknesses of the layers are optimized to allow transmission of infrared radiation and/or visible radiation through the layers and onto the one or more sensors. The light emitting diodes may be organic or inorganic.

Thus, embodiments of this disclosure provide improved transmission of infrared radiation and/or visible radiation without requiring extensive changes to the composition of the layers of the display.

The display may further comprise at least one conductor layer. The thickness of the at least one conductor layer may be optimized along with the thicknesses of the layers of insulator material.

A sensor of the one or more sensors may form part of a proximity and/or ranging sensing system which further comprises a radiation emitter.

A sensor of the one or more sensors may be an ambient light sensor.

The display may comprise four or more layers of insulator material.

The insulator material layers may consist of alternating layers of two different insulators.

The insulator material layers may be SiO₂ and SiN.

The layers may be optimized to allow transmission of radiation at a wavelength or wavelengths between 800 nm and 1000 nm.

The layers may be optimized to allow transmission of radiation at around 940 nm.

The layers may be optimized to allow transmission of radiation across a wavelength range of 450-650 nm.

The layers may be optimized to transmit in excess of 80% of infrared radiation at around 940 nm.

According to a second aspect of the invention there is provided a device comprising the system of claim 1. The device may be a mobile phone, a table computer, a laptop computer, a computer monitor, a car dashboard and/or navigation system, an interactive display in a public space, a home assistant, etc.

According to a third aspect of this disclosure, there is provided a method of optimizing transmission of infrared radiation and/or visible radiation through a display comprising two or more layers of insulator material, wherein the method uses as inputs the refractive indices and extinction coefficients of the layers, and minimum thicknesses of the layers, wherein the method comprises using a numerical optimization to determine the thicknesses of the layers which will optimize transmission of infrared radiation and/or visible radiation through the layers.

The display may further comprise at least one conductor layer.

The display may comprise four or more layers of insulator material.

A further input used by the method may be the order in which the layers are provided.

The method may allow the order in which the layers are provided to be changed if this improves transmission.

A further input may be a range of angles of incidence of the radiation onto the display.

The range of angles of incidence may be ±40° or a smaller range of angles.

The refractive indices and the extinction coefficients of the materials may be measured at a manufacturing facility at which the display will be manufactured.

The refractive indices and the extinction coefficients of the materials may be measured by depositing individual layers using the same technique that will be used during manufacture of the displays, and then measuring the refractive indices and the extinction coefficients of the deposited materials.

The layers may be optimized to transmit in excess of 80% of infrared radiation at around 940 nm.

The display may comprise an array of light emitting diodes and associated transistors supported by a substrate. A proximity sensor and/or an ambient light sensor may be provided beneath the display.

Finally, the present display system disclosed here utilises a novel approach at least in that transmission of material layers of the display has been optimized for infrared radiation and/or visible radiation.

### BRIEF DESCRIPTION OF THE PREFERRED EMBODIMENTS

Some embodiments of the disclosure will now be described by way of example only and with reference to the accompanying drawings, in which:

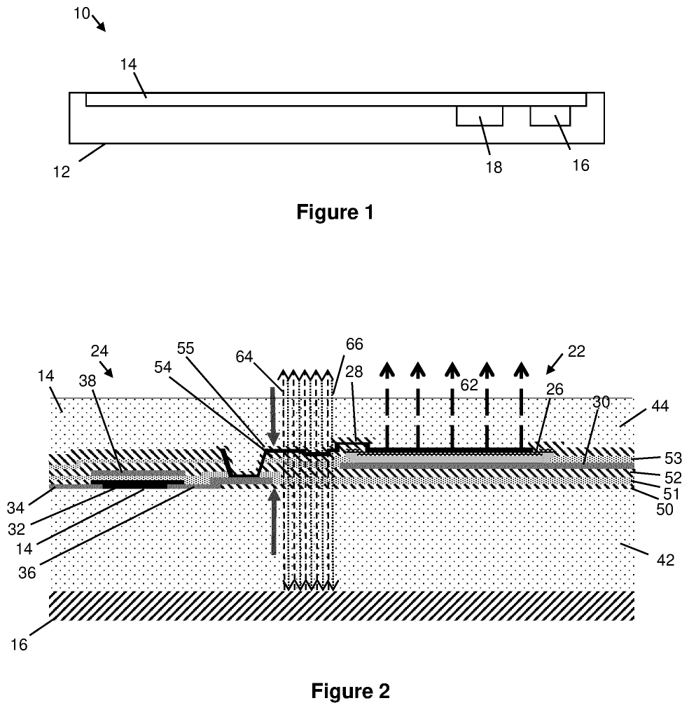

FIG. 1 schematically depicts in cross section a mobile phone with a display which may provide optimized transmission in accordance with the present disclosure;

FIG. 2 schematically depicts in more detail part of the mobile phone display and part of a sensor located beneath the mobile phone display;

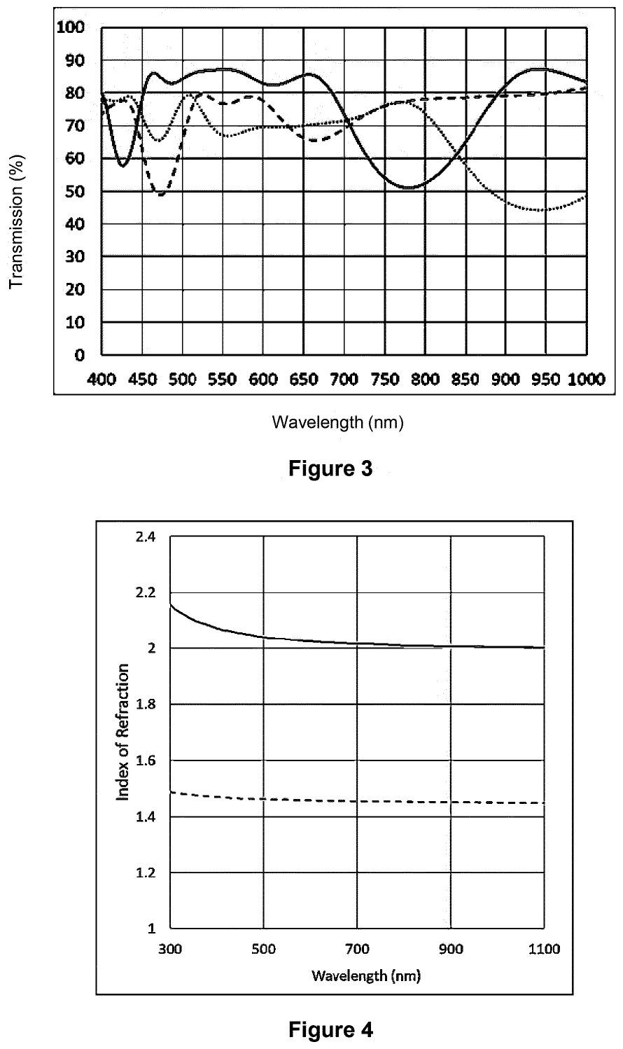

FIG. 3 is a graph which depicts transmission of material layers of the display as a function of wavelength, including transmission of material layers which have been optimized in accordance with the present disclosure;

FIG. 4 is a graph which depicts refractive indices used for material layers during optimization of the material layer thicknesses in accordance with the present disclosure;

FIG. 5 is a graph which depicts the refractive index used for an additional material layer during optimization of the material layer thicknesses in accordance with the present disclosure;

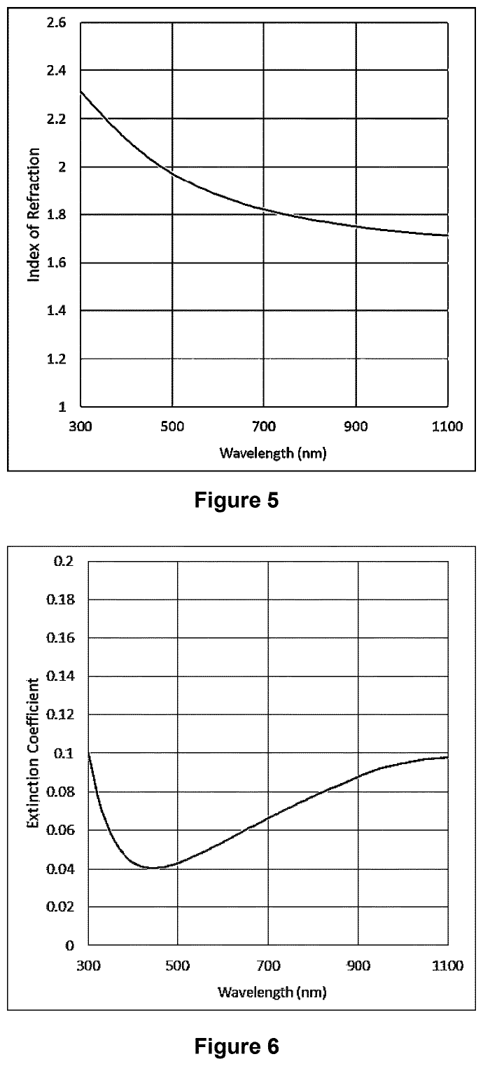

FIG. 6 is a graph which depicts the extinction coefficient used for the additional material layer during optimization of the material layer thicknesses in accordance with the present disclosure; and

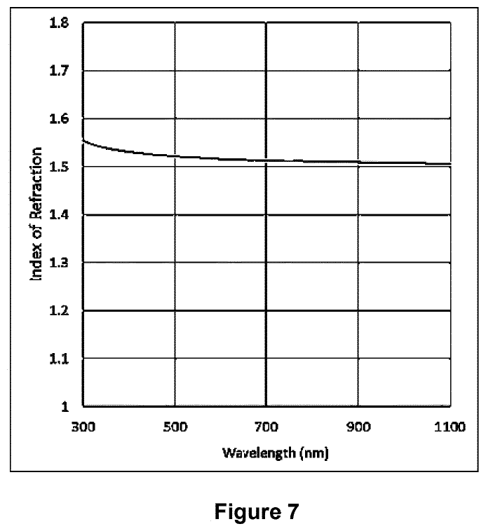

FIG. 7 is a graph which depicts the refractive index used during the optimization for glass which forms an upper layer and a lower layer of the display.

### DETAILED DESCRIPTION OF THE PREFERRED EMBODIMENTS

Generally speaking, the disclosure provides optimization of transmission of a display for radiation at wavelengths used by a sensor or a sensing system. The optimization may for example be for infrared radiation (e.g. at 940 nm). Additionally or alternatively the optimization may for example be for visible radiation (e.g. in the range 450-650 nm).

Some examples of the solution are given in the accompanying figures.

FIG. 1 is a schematic cross-sectional depiction of a mobile phone 10. The mobile phone comprises a housing 12 which holds a display 14. A proximity sensing system 16 is located beneath the display 14. Although the proximity sensing system 16 is depicted closed to one end of the display 14, the proximity sensing system may be provided at any location beneath the display. An ambient light sensor 18 is also located beneath the display 14. Again, the ambient light sensor 18 may be provided at any location beneath the display 14. Other components (not depicted) may also be provided in the mobile phone. These may include a processor, memory, a cellular modem and an RF transceiver.

The display 14 may for example be an LED array (e.g. an OLED array) which may be used to display content such as photographs, websites, emails, etc. to a user. The proximity sensing system is configured to determine the distance between the mobile phone 10 and objects in the proximity of the mobile phone. The proximity sensing system 16 comprises a source of radiation and one or more sensors. The one or more sensors may be configured as an array of photodiodes (e.g. single photon avalanche photodiodes). The radiation source may be configured to emit pulses of radiation. The proximity sensing system may be a time of flight system which is configured to measure the elapsed time between emission of a radiation pulse and detection of reflections of that pulse from one or more objects. This measurement may be performed by electronics which form part of the proximity sensing system 16. The output from the proximity sensing system may be processed to form a so called depth map, which indicates the distance to, and positions of, objects in the proximity of the mobile phone.

The radiation source of the proximity sensing system 16 may be configured to emit radiation at an infrared wavelength. This is desirable so that the emitted radiation is not visible to a user. The infrared radiation may for example have a wavelength in the range 800-1000 nm. The infrared radiation may for example have a wavelength of between 930 nm and 950 nm. The infrared radiation may for example have a wavelength of around 940 nm. Although it might be possible for the proximity sensing system 16 to emit ultraviolet radiation, which would not be seen by a user, this is not preferred because it is less efficient than using infrared radiation (more energy is required to generate the ultraviolet radiation and the ultraviolet radiation will suffer from stronger attenuation).

The ambient light sensor 18 may be configured to detect radiation in the visible spectrum (which may be referred to as visible light). The sensed level of ambient light may be used to determine for example the brightness of images displayed by the display 14. This is advantageous because it allows the display to be darker if ambient light is low, thereby using less power and prolonging the battery life of the mobile phone.

Other sensors and/or sensing systems may additionally or alternatively be located beneath the display 14. There are gaps (not depicted) between LEDs of the display LED array. It is these gaps which allow radiation to be incident upon the proximity sensing system 16 and the ambient light sensor 18. The proximity sensing system 16 may extend beneath a plurality of pixels (e.g. tens of pixels, e.g. around 50 pixels). The ambient light sensor 18 may extend beneath a plurality of pixels (e.g. tens of pixels, e.g. between 10 and 50 pixels).

FIG. 2 is a schematic cross section through a small portion of the display 14 and the proximity sensing system 16. A single organic light emitting diode 22 is depicted on the right hand side of FIG. 2, and a transistor 24 is depicted on the left hand side of FIG. 2. The transistor 24 may be a thin film transistor. The light emitting diode 22 comprises, in this example, organic LED (OLED) material layers 26. An anode 28 is connected to an upper surface of the OLED layers 26. A cathode 30 is connected to a lowermost surface of the OLED layers 26. In other embodiments the LED may be non-organic.

The transistor 24 comprises aSi, alGZO or other thin film transistor (TFT) material 32. A source 34 is located to the left of the TFT material, and a drain 36 is provided to the right of the TFT material. A gate 38 is provided above the TFT material 32. The anode 28 extends from the upper surface of the OLED layers 26 to the drain 36 of the transistor 24.

The components are all held on a substrate 42. The substrate 42 may for example be glass. A top layer 44 is provided on top of the LED 22 and thin film transistor 24. The top layer 44 may also be glass. The top layer protects the LED 22 and thin film transistor 24 whilst at the same time allowing the display to be seen by a user.

Various insulation layers are provided in order to keep components of the display 14 electrically isolated from one another. One or more of the insulation layers may be passivation layers. The passivation layer(s) may prevent corrosion by acting as a barrier against molecules such as water and sodium. In the depicted example, six layers of insulating material 50-55 are provided. Two different insulation materials that are often used in displays, SiO₂ and SiN, are included. SiO₂ is a common low-index, high-transparency insulator. SiN is sometimes preferred for certain layers due to its advantageous properties. Specifically, SiN may be used as an etch stop, as a thinner insulator with higher breakdown voltage, and/or as a protective layer due to its better diffusive properties (less moisture/oxygen migration). The layers of material may be referred to as a stack of layers.

A first layer 50 formed from a first insulation material is provided on the substrate 42. The first material may for example be SiO₂. A second layer 51 formed from a second insulation material is provided on top of the first layer 50. The second layer 51 separates the gate 38 from the thin film transistor material 32, and may also separate other conducting components from one another. The second material may for example be SiN. A third layer 52, formed from the first material, is provided on top of the second layer 51. The cathode 30 of the LED 22 may be located on top of part of the third layer 52. The cathode 30 may be formed from a metal such as aluminium, copper, silver, gold, titanium, or an alloy of one or more of those (such as AlCu). It could also be formed with a transmissive conductor like indium tin oxide (ITO). A fourth layer 53, formed from the second material, is provided on top of the third layer 52 (and on top of the cathode). A fifth layer 54, formed from the first material, is provided on top of the fourth layer 53. The anode 28 is provided on top of the fifth layer 54. The anode 28 may be formed from indium tin oxide (ITO). A sixth layer 55, formed from the first material, is provided on top of the anode 28. The first material and/or the second material may be passivation materials.

The LED 22 is schematically depicted as emitting radiation 62. This radiation passes through the anode 28 and the sixth insulation layer 55. Since the radiation passes through only two layers, it is relatively unaffected by those layers.

The proximity sensing system 16 is schematically depicted as emitting radiation 64 (the dashed arrows). Radiation which has been emitted by the proximity sensing system 16 will be reflected back towards the proximity sensor by objects. The reflected radiation 66 is depicted as being incident upon the proximity sensing system (the dotted arrows). As may be seen, the emitted radiation 64 passes through the six insulation layers 50-55 and also passes through the anode 28. The insulation layers 50-55 and the ITO anode 28 will attenuate the radiation 64. The reflected radiation 66 also passes through the six insulation layers 50-55 and the ITO anode 28, and again attenuation of the radiation will occur.

As noted further above, the radiation emitted and detected by the proximity sensing system 16 may be infrared radiation. The radiation may, for example be in the range 800-100 nm (e.g. around 940 nm).

FIG. 3 is a graph which depicts transmission of the stack of layers schematically depicted in FIG. 2 (at the position where radiation is emitted 64 and detected 66 by the proximity sensing system). The graph show transmission for wavelengths extending from 400 nm to 1000 nm. Transmission is indicated as a percentage. The transmissions were determined for thicknesses of the layers as set out in table 1 below:

TABLE 1

| | | | | |
|---|---|---|---|---|
| | | Non- | Worst | |
| | | Optimized | Case | Optimized |
| Layer | Material | Thickness | Thickness | Thickness |

Input Media (Glass)

| | | | | |
|---|---|---|---|---|
| Sixth insulation layer (first | SiO₂ | 200 nm | 125 nm | 215 nm |
| material) | | | | |
| Anode | ITO | 200 nm | 184 nm | 124 nm |
| Fifth insulation layer (first | SiO₂ | 200 nm | 124 nm | 139 nm |
| material) | | | | |
| Fourth insulation layer | SiN | 200 nm | 357 nm | 250 nm |
| (second material) | | | | |
| Third insulation layer (first | SiO₂ | 200 nm | 143 nm | 186 nm |
| material) | | | | |
| Second insulation layer | SiN | 200 nm | 128 nm | 275 nm |
| (second material) | | | | |
| First insulation layer (first | SiO₂ | 200 nm | 143 nm | 190 nm |
| material) | | | | |

Substrate Media (Glass)

In the non-optimized thickness example, each of the layers was provided with a thickness of 200 nm. The non-optimized thickness example is indicated by a dashed line. As may be seen from FIG. 3, the transmission for this example is generally speaking between 70 and 80%. However, at around 475 nm (blue light) the transmission drops below 50%. The transmission drops below 70% from around 630 nm to around 710 nm (red light). The transmission then increases slowly to just over 80% at 1000 nm.

This transmission is problematic for an ambient light sensor 18, because a) it is not as high as it could be and b) the response of the sensor will vary significantly as a function of the wavelength of the ambient light. The latter may cause the display to be brighter than needed for example if the ambient light happens to be dominated by a wavelength around 470 nm.

For the proximity sensing system 16, the transmission is around 78% at a wavelength of 940 nm. Although this is a reasonably good transmission, as noted above, the radiation must pass through the layers twice before being incident upon the sensor of the proximity sensing system 16. That is, the radiation emitted from the radiation source passes through the layers, is reflected from one or more objects, and then passes through the layers once more before the incident upon the sensor. Thus, the transmission figure of 78% must be squared for full effect, and this provides a final transmission figure of 61%. Furthermore, the display and the system it is part of may have other elements (such as polarizers, touch electronics, etc) in the optical path that further reduce transmission. Also, the intensity of radiation incident on an object and that reflected from an object and returning to the sensor both decrease as the square of the distance from that object. Any optimization to the display transmission will improve the signal-to-noise situation of the system. The present invention can be applied to any transmissive display technology that includes optimizable thin-film layers.

A dotted line in FIG. 3 depicts an example “worst case” scenario in which the same combination of material layers have thicknesses which give a very poor transmission at 940 nm (around 45%), and give poor transmission across most of the visible wavelength range. The poor transmission at 940 nm is particularly problematic because, as mentioned above, the transmission figure must be squared for full effect. This gives a transmission figure of 20%. The thicknesses of the layers are listed under the heading Worst Case Thickness in Table 1. Although this is a worst case scenario, generated using a numerical simulation, similarly poor transmission as this may occur for a given display if that display happens to have layer thicknesses which perform poorly at 940 nm.

The solid line in FIG. 3 depicts the transmission of the same combination of layers, but with thicknesses of the layers selected to optimize transmission at 940 nm and also optimize transmission in the range of 450-650 nm. The thicknesses of the layers are listed on the right hand side of Table 1. As may be seen, the transmission between 450-650 nm is generally above 80%. The transmission varies by less than 10%. Because the transmission is high, and the variations are relatively low (compared with the non-optimized example), the performance of the ambient light sensor 18 is more consistent for visible light across all wavelengths. In other words, the display screen will not be made excessively bright for example due to poor transmission of ambient light at around 470 nm as would be the case with the non-optimized example.

At 940 nm the transmission of the stack of layers is around 87%. As mentioned above this value must be squared because the infrared radiation passes through the stack of layers twice. The resulting transmission value is 76%. This is a significant increase over the non-optimized value of 61%. It is a very substantial increase over the worst case thickness value of 20% (almost a 4× increase). As noted above, due to the inverse square fall-off of intensity of reflected radiation for the proximity sensing system 16, this significant increase of transmission of infrared radiation is particularly advantageous.

The optimization improves transmission because material layer thickness has a direct effect upon transmission. In addition to bulk light absorption due to the layer material's extinction property and its thickness, in thin films there will be some amount of constructive and/or destructive interference that affects overall transmission. The interference will depend on the wavelength of the light in the material (which is related to the incident wavelength of light and the index of refraction of the material), the thickness of the material, and the properties of the materials that the light enters before and after.

The refractive index n and the extinction coefficient k of each material present in the stack of layers, together with the order of the layers, were provided as inputs for the optimization. FIG. 4 is a graph which depicts the refractive index n that was used for SiN (solid line) and SiO₂ (dashed line) as a function of wavelength. The extinction coefficient k was effectively zero across the wavelengths of interest. In other embodiments, non-zero values of k are used when appropriate. FIG. 5 is a graph which depicts the refractive index n that was used for the ITO as a function of wavelength. FIG. 6 is a graph which depicts the extinction coefficient k that was used for the ITO as a function of wavelength. The optimization was also provided with a minimum layer thickness of 124 nm and a maximum layer thickness of 375 nm. The optimization was set the task of maximising transmission of radiation at 940 nm and radiation at 450-650 nm. The radiation was assumed to be incident upon the stack of layers at normal incidence. In other cases the optimization might be done at a different angle, over a range of angles (e.g. +−15 degrees, +−30 degrees), or even over a particularly weighted angular distribution such as Lambertian. The thicknesses of the layers were the only optimization variables. In other cases the optimization may also allow the number of layers, the material n, and/or the material k to be variables for optimization.

The optimization had a target transmission profile T₀(λ) which was 100% transmission at the wavelengths mentioned above. The transmission T was determined primarily as a function of incident angles θ, incident wavelengths λ, N layers L_{1 . . . N}, as well an input media and a substrate media. In this example the input media and substrate media were both set as glass with no absorption. The transmission function can be expressed in the form of a complex conjugate multiplication:

$$T ( λ , θ , {L}_{1 … N} ) = {( \frac{2 {γ}_{0}}{{γ}_{0} {M}_{11} + {γ}_{0} {γ}_{s} {M}_{12} + {M}_{21} + {γ}_{s} {M}_{22}} ) ( \frac{2 {γ}_{0}}{{γ}_{0} {M}_{11} + {γ}_{0} {γ}_{s} {M}_{12} + {M}_{21} + {γ}_{s} {M}_{22}} )}^{*}$$

where subscript “0” represents the input layer, or input media and subscript “s” indicates the substrate, or exit layer. γₘ is given by the expression:

γₘ≡nₘ\sqrt{ε₀μ₀} cos θₘ

where nₘ is the complex index of refraction (nₘ=nₘ+ikₘ) for layer (or media) m, and θₘ is the angle of travel in layer (or media) m, related by Snell's law to the angle of incidence θ (which was set at 0° off normal in the optimization used to generate the transmission results of FIG. 3). The M₁₁, M₁₂, M₂₁, M₂₂ in the transmission equation are the elements of a 2×2 matrix M, which is a transfer matrix that represents the cumulative effect the stack of materials has on the electromagnetic fields of light as it travels through the stack.

$$M = ( \begin{matrix}{M}_{11} & {M}_{12} \\ {M}_{21} & {M}_{22}\end{matrix} ) = {\prod }_{m = 1}^{N} {M}_{m}$$

Each Mₘ in the product is the transfer matrix for layer Lₘ, given by:

$${M}_{m} = ( \begin{matrix}cos {δ}_{m} & \frac{i sin {δ}_{m}}{{\underline{n}}_{m}} \\ i {\underline{n}}_{m} sin {δ}_{m} & cos {δ}_{m}\end{matrix} )$$

where δₘ represents the “phase thickness” of the layer Lₘ with thickness tₘ and is given by

$${δ}_{m} = \frac{2 π}{λ} {\underline{n}}_{m} {t}_{m} cos {θ}_{m}$$

An example of the derivation of a formalism similar to this is found in Thin-Film Optical Filters, 3^{rd} Edition, Angus MacLeod [pgs 37-54], which explains in detail how a thin film stack transmission function may be derived. Thin film stack transmission functions are well known and may be found in various references. The optimization outlined herein may be similarly performed for other forms of the transmission function.

A merit function was determined:

$$Merit Function ( λ , θ , {L}_{1 … N} ) = {( \frac{1}{W} {\sum }_{j = 1}^{W} {( T ( {λ}_{j} , θ , {L}_{1 … N} ) - {T}_{0} ( {λ}_{j} ) )}^{2} )}^{1 / 2}$$

where W is the number of wavelengths over which the merit function was determined. Other forms of merit functions may be used that, for example, weight the relative importance of the target transmission at different wavelengths. Although this example uses the square of the residual differences, other metrics may be used.

The optimization method sought to minimize the merit function (i.e. minimize the residual difference function shown above). The optimization method used the “Newton” method, which recursively looks for local minima of the merit function using the first and second derivatives (or gradients) of the merit function (the derivatives are with respect to the critical parameters, in this case the layer thicknesses). The gradients are used to suggest changes to the thicknesses. As the first derivatives approach zero so do the suggested changes, eventually reaching a local minimum (the second derivatives can be used to confirm whether this is a local minimum or not). After evaluating a number of local starting conditions and finding one or more local minima, the lowest local minimum was selected as the best solution found. In some instances with a different form of the merit function, the numerical optimization method may seek to maximise the function rather than minimizing the function.

Other numerical optimization methods may be used, such as relaxed-Newton, Monte-Carlo, gradient descent, etc.

These optimization methods may use the starting parameters and variables which are set out above. Optimization methods may use other starting parameters and variables, as is explained below.

The maximum and minimum thicknesses of the layers of material should be defined for the optimization. A relevant consideration for the minimum layer thickness is that insulating layers should be capable of properly acting as insulators (so that short-circuits between conductors do not occur). There may be some variation (also known as tolerance) between the intended thickness of a layer of material on a display and the actual thickness of the material that is provided on the display. In a given display manufacturing facility a maximum allowable variation of the thickness may be known. Where this is the case, the optimization for the thicknesses of layers of the display made in that manufacturing facility may take the maximum allowable variation into account. The optimization may use a minimum thickness which is the minimum thickness needed to avoid short circuits plus the maximum allowable variation of the thickness in that manufacturing facility.

In the example described above, a minimum layer thickness of 124 nm was used. However, other minimum layer thicknesses may be used. The minimum layer thickness may for example be 100 nm. The minimum thickness may be less than 100 nm. The minimum thickness may vary for example due to details of the electrical insulation requirements for the circuit which drives the display (which depend on voltages used, areas of the conductors, other pixel circuit and perimeter circuit design details. The minimum thickness may vary for example due to the electrical insulation properties of the materials used. As noted above, the minimum thickness may also vary due to manufacturing plant (fab) tolerances (which in turn may depend on fabrication equipment uniformity and control, as well as on the size of the fabrication area).

In the example described above, the maximum thickness is set at 375 nm. Although it would be possible to use even thicker material, providing a thicker layer requires more time (and thus cost). In addition, if the layer is relatively thick then it may be hard to etch fully through the layer to form vias which connect between conductors in different layers. Problematically uneven surface topologies of layers may be caused. In general, a thicker layer of material will absorb more radiation than a thinner layer of material. Thicker material is thus undesirable, given that the maximum transmission of radiation at some wavelengths is the aim of the optimization. Indeed, in the optimized example, although the optimization allowed the material layer thickness to vary up to 375 nm, the thickest layer in the optimized stack is well under 300 nm.

Although the maximum layer thickness in the example is 375 nm, other maximum layer thicknesses may be used. For example, a maximum layer thickness of 300 nm may be used. The optimization may be run without specifying a maximum thickness, although this will increase the time required for the optimization to run (the optimization will attempt to accommodate an infinite maximum thickness). In general, it may be desirable to set a maximum layer thickness to improve speed of calculation. The maximum layer thickness may be set to correspond with the maximum thickness of the layer that can be fabricated.

Although the optimization was performed for a particular combination of layers of materials, the optimization may be performed for any combination of any material layers. The number of material layers and the order in which the layers will be provided may be provided as inputs for the optimization. The refractive index n and absorption k of each material that will be used to form a layer should be included in the optimization.

Once material layer parameters and incidence angle parameters have been provided, the optimization may be run as set out above. The optimization may for example be run solely to optimize transmission at 940 nm or some other infrared wavelength (e.g. if an ambient light sensor is not present beneath the display). Equally, the optimization may be performed for just the range 450-650 nm (or some other range of visible wavelengths), e.g. if a proximity sensor is not located beneath the display. The optimization may be run for a combination of a desired infrared wavelength and a desired range of visible wavelengths.

The number of layers in the optical path and the materials which constitute those layers may be determined based upon operational requirements of the display. In general, at least two-to-four routing layers are common (the routing layers will include conducting areas). At least two-to-four clear dielectric/passivation/etch-stop layers (which are insulating layers) are commonly associated with the routing layers. Additionally, at least one thin-film transistor material layer may also be present, with an associated one-to-two dielectric/passivation/etch-stop layers (which are insulating layers). Furthermore, one-to-four light emitting materials may comprise additional layers, with an associated one-to-four dielectric/passivation/etch-stop layers (which are also insulating layers). Therefore the number of clear dielectric/passivation/etch-stop layers (insulating layers) may often be two or more (typically four or more), and may be up to ten. However more may be used in some instances. Additionally, in many cases at least one of the two-to-four routing layers may include areas of transparent conductors.

The refractive index n and extinction coefficient k values for the materials in the layer stack may depend upon the concentration of impurities in the material. The refractive index and extinction coefficient of a material used for the optimization may be provided by a manufacturer of that material. In some instances there may be some variation of refractive index and extinction coefficient of a material which is not identified by the supplier of that material. In a given display manufacturing facility, the refractive index and/or absorption of a material that is being used to manufacture displays may be measured. The optimization may be run using the measured value. Measurements of the refractive index and/or absorption of a material may be performed periodically, and the optimization may be run periodically. For example, the parameters n, k of the materials will be monitored periodically by the fab and if they (or a measured transmission of the display) are found to drift beyond a predetermined threshold the optimization may be rerun. This allows the thicknesses of the material layers to be adjusted to take into account variation of the refractive index and/or absorption of a material which is being used in the layer stack. Advantageously, this may maintain good transmission of manufactured layer stacks over a prolonged period of time (compared with the transmission deteriorating as the refractive index and/or absorption of a material used in manufacture varies over time and moves away from a value used in the optimization).

The refractive index and/or extinction coefficient of a material layer may also depend upon the deposition technique which is used to form that material layer (the density profile and impurity profile of the material is affected by the deposition technique). In a given display manufacturing facility, a layer of material may be formed using the same technique that will be used during manufacture. The refractive index and/or absorption of that layer of material may then be measured. The optimization may be run using the measured value. This may provide a higher transmission of the material layer stack, because values used by the optimization correspond more closely with properties of the materials in production displays.

In general, the number of layers of a display and the materials which may up the display may be determined based upon functional requirements of the display. These may be fixed by the display manufacturer based upon the display's requirements. The minimum thicknesses of those layers may also be determined based upon functional requirements of the display. Once these constraints are known, the thicknesses of the layers may be selected to provide improved transmission of radiation at one or more wavelengths (or wavelength ranges). This advantageously allows a sensor or sensors located beneath the display to operate more effectively.

In some instances, the display manufacturer may provide some flexibility in the number of layers of material that are used to form the display. Where this is the case, the optimization may be run for different possible numbers of layers to determine which provides the best transmission.

In some instances, the display manufacturer may provide some flexibility in the order in which the layers of material used to form the display are deposited. Where this is the case, the optimization may be run for different possible orders of layers to determine which provides the best transmission.

In some instances, the display manufacturer may provide some flexibility in the materials which are used to form the display. Where this is the case, the optimization may be run for different possible combinations of materials to determine which provides the best transmission.

In some instances, for a given material, it may be possible to use different implementations of that material which have different refractive indices and/or different extinction coefficients. Where this is the case, the optimization may be run for different implementations of the material to determine which provides the best transmission.

The embodiment of the invention has been described in connection with a proximity sensing system 16. However, the invention may additionally or alternatively be implemented with a ranging sensing system (i.e. a system which may provide a depth map indicating the distance to objects and surfaces in the vicinity of the system).

The embodiment of the invention has been described for insulator materials (SiO₂, SiN) commonly used in a display. These are examples of dielectric materials. However, the invention may be used with other insulator (e.g. dielectric) materials. Other insulator materials which may be used for example are: diamond like carbon, other silicates, other nitrides, or tantalum oxides. In addition to acting as insulators, some material layers of the display may act to provide passivation. Some material layers may serve the purpose of etch stop for a material that is deposited and etched above them. These material layers may also be insulators. Occasionally layers may have an optical purpose as well (such as lensing). Some material layers may not be insulators.

The embodiment of the invention has been described for a transparent conductor material (ITO) commonly used in a display. Other transparent/semi-transparent conductors which may be used for example are: metal nanowires, carbon nanotubes, polythiophene. If a display includes conductors which are not transparent (and which are not semi-transparent), then the optimization may be performed for areas of the display where the non-transparent conductors are not present.

The minimum thickness used by the optimization may be different for different layers. For example, a conductor layer may be thinner (or thicker) than an insulation layer. The minimum thicknesses of the layers will depend upon the material used to form the layers and the functionality that the layers are required to provide.

The optimization described above is directed towards a single stack of material layers. However, in some instances there may be two different stacks of material layers within the display which both transmit radiation onto a sensor (e.g. a stack which includes an anode such as ITO and a stack which does not). In such a situation the optimization may be performed for both stacks of material layers, with the optimized thicknesses being the thicknesses which give the greatest combined transmission. The optimization may apply weightings to the different stacks of material layers. For example the weightings may take into account different surface areas of the stacks which are located above the sensor. The optimization may be performed for a combination of two, three or more different stacks of material layers.

The optimization described above is directed towards a stack of material layers which includes a conductor (ITO). However, in some instances optimization may be performed for a stack of material layers that does not include a conductor (e.g. if a substantial proportion of the area above a sensor does not include a conductor). In general, optimization may be performed for two or more material layers.

Embodiments of the present disclosure can be employed in many different applications including, for example, in the mobile phone industry and other industries.

In this document references to “optimizing” the transmission of layers of material are intended to mean performing a method that seeks to provide improved transmission compared with the transmission that is conventionally achieved.

Embodiments of the invention may be used in any device where a sensor is located behind a display. For example, the device may be a phone, a table computer, a laptop computer, a computer monitor, a car dashboard and/or navigation system, an interactive display in a public space, a home assistant, etc.

List of reference numerals:

| | |
|---|---|
| 10 | Mobile phone |
| 12 | Housing |
| 14 | Display |
| 16 | Proximity sensing system |
| 18 | Ambient light sensor |
| 22 | Light emitting diode |
| 24 | Transistor |
| 26 | OLED material layers |
| 28 | Anode |
| 30 | Cathode |
| 32 | Thin film transistor material |
| 34 | Source |
| 36 | Gate |
| 42 | Substrate |
| 44 | Top layer |
| 50 | First layer |
| 51 | Second layer |
| 52 | Third layer |
| 53 | Fourth layer |
| 54 | Fifth layer |
| 55 | Sixth layer |
| 62 | Radiation emitted by light emitting diode |
| 64 | Radiation emitted by proximity sensing system |
| 66 | Reflected radiation incident upon proximity sensing system |

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

1. A system comprising a display and one or more sensors, the one or more sensors being located beneath the display, wherein the display comprises an array of light emitting diodes and associated transistors supported by a substrate, wherein the display further comprises two or more layers of insulator material, and wherein thicknesses of the layers are optimized to allow transmission of infrared radiation and/or visible radiation through the layers and onto the one or more sensors.

2. The system of claim 1, wherein the display further comprises at least one conductor layer.

3. The system of claim 1, wherein a sensor of the one or more sensors forms part of a proximity and/or ranging sensing system which further comprises a radiation emitter.

4. The system of claim 1, wherein a sensor of the one or more sensors is an ambient light sensor.

5. The system of claim 1, wherein the display comprises four or more layers of insulator material.

6. The system of claim 1, wherein the insulator material layers consist of alternating layers of two different insulators.

7. The system of claim 5, wherein the insulator material layers are SiO₂ and SiN.

8. The system of claim 1, wherein the layers are optimized to allow transmission of radiation at a wavelength or wavelengths between 800 nm and 1000 nm.

9. The system of claim 8, wherein the layers are optimized to allow transmission of radiation at around 940 nm.

10. The system of claim 1, wherein the layers are optimized to allow transmission of radiation across a wavelength range of 450-650 nm.

11. The system of claim 1, wherein the layers are optimized to transmit in excess of 80% of infrared radiation at around 940 nm.

12. A mobile phone comprising the system of claim 1.

13. A method of optimizing transmission of infrared radiation and/or visible radiation through a display comprising two or more layers of insulator material, wherein the method uses as inputs the refractive indices and extinction coefficients of the layers, and minimum thicknesses of the layers, wherein the method comprises using a numerical optimization to determine the thicknesses of the layers which will optimize transmission of infrared radiation and/or visible radiation through the layers.

14. The method of claim 13, wherein the display further comprises at least one conductor layer.

15. The method of claim 13, wherein a further input used by the method is the order in which the layers are provided.

16. The method of claim 13, wherein the method allows the order in which the layers are provided to be changed if this improves transmission.

17. The method of claim 13, wherein a further input is a range of angles of incidence of the radiation onto the display.

18. The method of claim 17, wherein the range of angles of incidence is ±40° or a smaller range of angles.

19. The method of claim 13, wherein the refractive indices and the extinction coefficients of the materials are measured at a manufacturing facility at which the display will be manufactured.

20. The method of claim 19, wherein the refractive indices and the extinction coefficients of the materials are measured by depositing individual layers using the same technique that will be used during manufacture of the displays, and then measuring the refractive indices and the extinction coefficients of the deposited materials.

21. The method of claim 13, wherein the layers are optimized to transmit in excess of 80% of infrared radiation at around 940 nm.

22. The method of claim 13, wherein the display comprises an array of light emitting diodes and associated transistors supported by a substrate, and wherein a proximity sensor and/or an ambient light sensor is provided beneath the display.
